(19) United States
(12) Patent Application Publication
(10) Pub. No.: US 2026/0247890 A1
(43) Pub. Date: Aug. 20, 2026

(54) SUBSTRATE PROCESSING METHOD AND SUBSTRATE PROCESSING APPARATUS

(71) Applicant: Tokyo Electron Limited, Tokyo (JP)

(72) Inventors: Ryo YAMAMOTO, Kumamoto (JP); Koji KAGAWA, Kumamoto (JP); Itaru KANNO, Kumamoto (JP)

(21) Appl. No.: 19/535,437

(22) Filed: Feb. 10, 2026

(30) Foreign Application Priority Data
Feb. 14, 2025 (JP) 2025-022619

(51) Int. Cl. H10P 50/66; H10P 72/00

(52) U.S. Cl. CPC H10P 50/667; H10P 72/0408; H10P 72/0414

(57) ABSTRACT

A substrate processing method includes providing a substrate including a recess and having a region in which a metal is exposed on at least a portion of a side surface or a bottom surface of the recess; oxidizing the exposed metal with a first processing liquid, and after the oxidizing, etching the oxidized metal with a second processing liquid.

### CROSS REFERENCES TO RELATED APPLICATIONS

This application is based on and claims priority from Japanese Patent Application No. 2025-022619, filed on Feb. 14, 2025, with the Japan Patent Office, the disclosure of which is incorporated herein in its entirety by reference.

### TECHNICAL FIELD

The present disclosure relates to a substrate processing method and a substrate processing apparatus.

### BACKGROUND

In the related art, in a stacked structure in which an insulating film and a metal film such as TiN, which is difficult to remove by wet etching, are alternately stacked, a method of selectively removing a portion of the metal film has been known. The method involves heating a substrate in an air atmosphere to oxidize a portion of the metal film such as TiN to make the metal film easy to be wet-etched, and then performing wet etching with a chemical liquid capable of removing the oxide film (see, e.g., International Patent Publication WO 2018/230377).

### SUMMARY

According to an embodiment of the present disclosure, a substrate processing method includes providing a substrate including a recess and having a region in which a metal is exposed on at least a portion of a side surface or a bottom surface of the recess; oxidizing the exposed metal with a first processing liquid; and after the oxidizing, etching the oxidized metal with a second processing liquid.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic plan view illustrating the overall configuration of a substrate processing system which is one aspect of a substrate processing apparatus.

FIG. 2 is a schematic longitudinal cross-sectional view illustrating a configuration example of a processing unit incorporated into the substrate processing system of FIG. 1.

FIG. 3 is a schematic cross-sectional view illustrating an example of a stacked structure of a substrate that may be processed by a substrate processing method, according to an embodiment.

FIG. 4 is a schematic cross-sectional view illustrating TiN included in the stacked structure illustrated in FIG. 3 being etched by a substrate processing method, according to an embodiment.

FIG. 5 is a flowchart illustrating a series of processes performed in a substrate processing method, according to an embodiment.

FIG. 6 is a schematic cross-sectional view illustrating a configuration of a sample used in an experiment conducted to confirm the effect of a substrate processing method, according to an embodiment.

FIG. 7 is a graph illustrating the results of the experiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, certain aspects for implementing a substrate processing apparatus (e.g., substrate processing system) and a substrate processing method performed using the substrate processing apparatus (hereinafter referred to as “embodiments”) according to the present disclosure will be described in detail with reference to the drawings. In addition, the present disclosure is not limited to these embodiments.

### <Overall Configuration of Substrate Processing System>

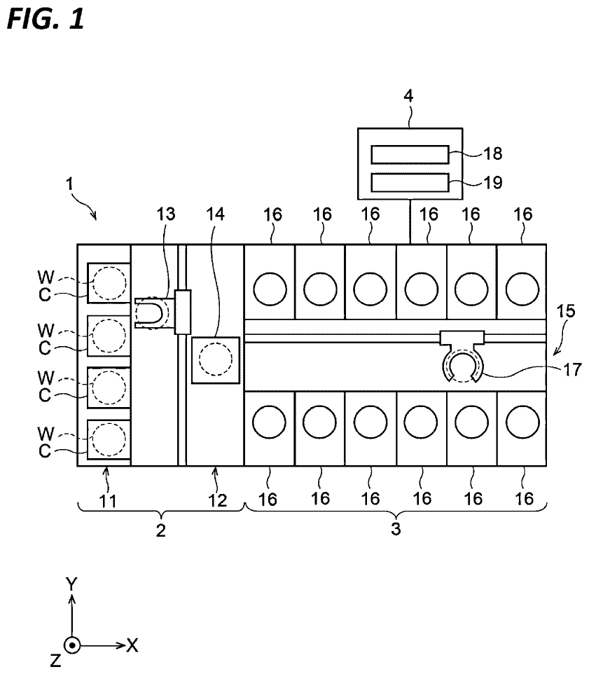

First, the overall schematic configuration of a substrate processing system 1 according to an embodiment of the substrate processing apparatus will be described with reference to FIG. 1. FIG. 1 is a diagram illustrating a schematic configuration of the substrate processing system 1, according to a first embodiment. Hereinafter, in order to clarify the positional relationship, X-axis, Y-axis, and Z-axis, which are orthogonal to each other, are defined, in which a Z-axis forward direction is defined as a vertical upward direction.

As illustrated in FIG. 1, the substrate processing system 1 (e.g., the substrate processing apparatus) includes a loading and unloading station 2 and a processing station 3.

The loading and unloading station 2 includes a carrier placing unit 11 and a transfer unit 12. A plurality of carriers C (e.g., FOUP) are placed on the carrier placing unit 11. A plurality of substrates W (e.g., semiconductor wafers) are accommodated in each carrier C in a horizontal posture at equal intervals in the vertical direction.

The transfer unit 12 includes a substrate transfer device 13 and a delivery unit 14 provided therein. The substrate transfer device 13 includes a multi-axis transfer robot or a multi-joint transfer robot. The substrate transfer device 13 holds a wafer using a fork-shaped wafer holder as an end effector, and transfers the substrate W between the carrier C and the delivery unit 14.

The processing station 3 includes a transfer unit 15 and a plurality of processing units 16.

A substrate transfer device 17 is provided inside the transfer unit 15. The substrate transfer device 17 includes a multi-axis transfer robot or a multi-joint transfer robot. The substrate transfer device 17 holds a wafer using a fork-shaped wafer holder as an end effector, and transfers the substrate W between the carrier C and the delivery unit 14.

The processing unit 16 performs a liquid processing by supplying a processing liquid to the substrate W carried in the processing unit 16 by the substrate transfer device 17.

The substrate W accommodated in the carrier C is taken out by the substrate transfer device 13 of the transfer unit 12 and carried into the delivery unit 14. The substrate W is taken out by the substrate transfer device 17 of the transfer unit 15 and carried into the processing unit 16. The wafer processed in the processing unit 16 is returned to the original carrier C along a reverse route.

The substrate processing system 1 includes a control device 4 as illustrated in FIG. 1. The control device 4 may control the operations of all operable components included in the substrate processing system 1. The control device 4 is, for example, a computer, and includes a control operation unit 18 and a storage unit 19. The storage unit 19 stores a program (e.g., including a processing recipe that determines the sequence of processes) for controlling various processes performed in the substrate processing system 1. The control operation unit 18 reads the program stored in the storage unit 19 and executes the same to control the operation of the substrate processing system 1. The control operation unit 18 may be a central processing unit (CPU) or one or a plurality of circuits.

In addition, the program may be recorded in a computer-readable storage medium and installed in the storage unit 19 of the control device 4 from the storage medium. Examples of the computer-readable storage medium may include any one of a hard disk (HD), a flexible disk (FD), a compact disk (CD), a magnet optical disk (MO), a memory card, a random access memory (RAM), a read only memory (ROM), a solid state drive (SSD), or a combination of two or more of these.

### <Configuration of Processing Unit 16>

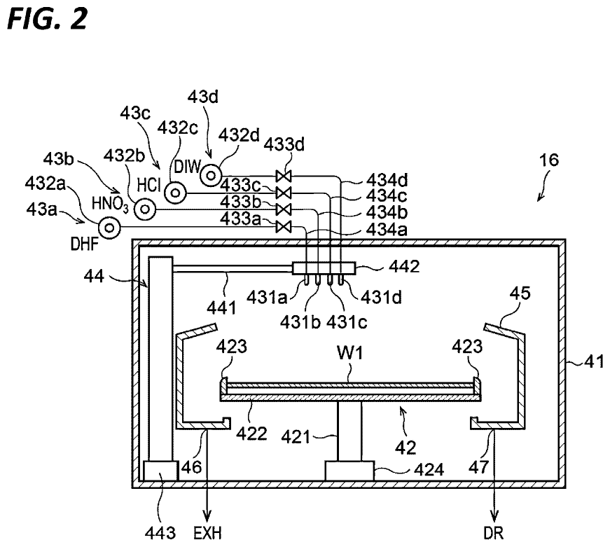

Next, the configuration of the processing unit 16 will be described with reference to FIG. 2.

The processing unit 16 has a configuration necessary to perform a series of liquid processing steps for etching the TiN film, which will be described in detail below, on the substrate W.

The processing unit 16 includes a chamber 41, and a substrate holding unit 42 provided in the chamber 41.

The substrate holding unit 42 includes a rotating shaft 421 extending vertically within the chamber 41, a turntable 422 attached to an upper end of the rotating shaft 421, a chuck 423 provided on the outer periphery of the upper surface of the turntable 422 and supporting the outer periphery of the substrate W, and a driving unit 424 that drives the rotating shaft 421 to rotate.

The substrate W is supported by the chuck 423 and horizontally held on the turntable 422 while being slightly spaced apart from the upper surface of the turntable 422. According to the present embodiment, the method for holding the substrate by the substrate holding unit 42 may employ a so-called mechanical chuck type, for example, a movable chuck 423 gripping an outer peripheral portion of the substrate W. Alternatively, the method may employ a so-called vacuum chuck type that vacuum-suctions the rear surface of the substrate W.

A base end of the rotating shaft 421 is rotatably supported by the driving unit 424, and a distal end of the rotating shaft 421 supports the turntable 422 horizontally. As the rotating shaft 421 is rotated, the turntable 422 attached to the upper end of the rotating shaft 421 is rotated, and accordingly, the substrate W, which is held on the turntable 422 while being supported by the chuck 423, is rotated. A controller 3 controls the operation of the driving unit 424 and controls a rotation timing, a rotation speed, and the like, of the substrate W.

The processing unit 16 includes a dilute hydrofluoric acid supply 43a, a concentrated nitric acid supply 43b, a hydrochloric acid supply 43c, and a rinse liquid supply 43d. The dilute hydrofluoric acid supply 43a, the concentrated nitric acid supply 43b, the hydrochloric acid supply 43c, and the rinse liquid supply 43d are also collectively referred to as a processing liquid supply.

The dilute hydrofluoric acid supply 43a includes a nozzle 431a for discharging dilute hydrofluoric acid (also simply referred to as “DHF”) with respect to the substrate W held by the substrate holding unit 42, and a DHF supply source 432a for supplying DHF to the nozzle 431a. The DHF supply source 432a may be a tank or may be provided as a factory default. DHF is supplied to the nozzle 431a at a controlled flow rate from the DHF supply source 432a through a supply pipe 434a in which a flow control device 433a (e.g., on-off valve, flow control valve, and/or flow meter) is interposed.

The concentrated nitric acid supply 43b includes a nozzle 431b for discharging the concentrated nitric acid (also simply referred to as “HNO₃”) with respect to the substrate W held in the substrate holding unit 42, and an HNO₃ supply source 432b for supplying HNO₃ to the nozzle 431b. The HNO₃ supply source 432b may be a tank or may be provided as a factory default. HNO₃ is supplied to the nozzle 431b at a controlled flow rate from the HNO₃ supply source 432b through a supply pipe 434b in which a flow control device 433b (e.g., an on-off valve, a flow control valve, and/or a flow meter) is interposed. In the present embodiment, as for HNO₃, nitric acid having a concentration of, for example, about 60 to 70 wt % (or higher) may be used.

The hydrochloric acid supply 43c includes a nozzle 431c for discharging hydrochloric acid (also simply referred to as “HCl”) with respect to the substrate W held in the substrate holding unit 42, and an HCl supply source 432c for supplying the HCl to the nozzle 431c. The HCl supply source 432c may be a tank or may be provided as a factory default. The HCl is supplied to the nozzle 431c at a controlled flow rate from the HCl supply source 432c through a supply pipe 434c in which a flow control device 433c (e.g., an on-off valve, a flow control valve, and/or a flow meter) is installed. In the present embodiment, as for the HCl, dilute HCl (e.g., DHCl, diluted with water) having a concentration of, for example, about 5 wt % to 10 wt % is used.

The rinse liquid supply 43d includes a nozzle 431d for discharging deionized water (DIW) as a rinse liquid with respect to the substrate W held in the substrate holding unit 42, and a rinse liquid supply source 432d for supplying the rinse liquid to the nozzle 431d. The rinse liquid supply source 432d may be generally provided as a factory default. The rinse liquid is supplied to the nozzle 431d at a controlled flow rate from the rinse liquid supply source 432d through a supply pipe 434d in which a flow control device 433d (e.g., an on-off valve, a flow control valve, and/or a flow meter) is installed.

Two or more types of processing liquids (e.g., DHCl and rinse liquid) may be selectively supplied to the substrate W from the same nozzle.

The processing unit 16 may include a nozzle that discharges an organic solvent for drying such as, for example, isopropyl alcohol (IPA) to the substrate W disposed in the substrate holding unit 42 and a supply for the organic solvent supply source that supplies the organic solvent for drying to the nozzle. In addition, the processing unit 16 may include a supply for drying gas including a nozzle for discharging the drying gas such as nitrogen gas, dry air, and the like to the substrate W held in the substrate holding unit 42, and a supply for the drying gas supply source that supplies the drying gas to the nozzle.

The processing unit 16 includes a nozzle moving mechanism 44 that drives the nozzles 431a to 431d. The nozzle moving mechanism 44 includes an arm 441, a moving body 442 with a built-in drive mechanism, which is movable along the arm 441, and a rotating and elevating mechanism 443 that rotates and elevates the arm 441. The nozzles 431a to 431d are attached to the moving body 442. The nozzle moving mechanism 44 may move the nozzles 431a to 431d between a position above the center of the substrate W held in the substrate holding unit 42 and a position above the circumferential edge of the substrate W, and may further move the nozzles to a standby position outside a cup 45 to be described below when viewed in a plan view. In the present embodiment, the nozzles 431a to 431d are held by a common arm, but may be held in separate arms and moved independently.

The processing unit 16 includes the cup 45 (e.g., a liquid tray cup). The cup 45 is provided around the substrate holding unit 42, and receives and collects various processing liquids (e.g., a cleaning liquid, and a rinse liquid) scattered from the substrate W. The cup 45 is provided with an elevating mechanism (not illustrated) that drives the cup 45 in the vertical direction, an exhaust port 46 that exhausts the atmosphere in the cup 45, and a drain port 47 that drains various processing liquids scattered from the substrate W from the cup 45. In addition, the cup 45 has a configuration that can change the exhaust and drainage destinations according to the type of liquid (e.g., acid, alkali, or organic). Such a configuration is well known in the technical field of the semiconductor manufacturing apparatus, and therefore, illustrations and detailed descriptions thereof are omitted.

Next, an example of processing on the substrate W performed in the processing unit 16 will be described.

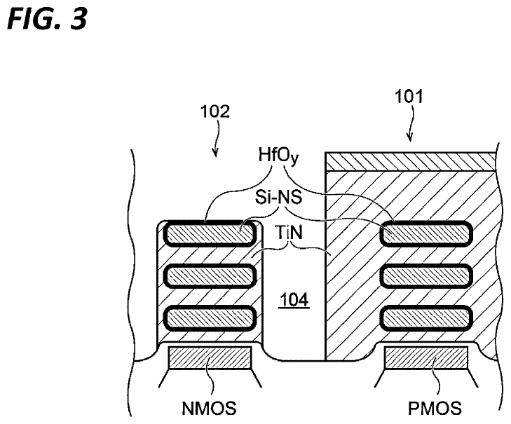

The substrate processing method according to an embodiment of the present disclosure may be used, for example, for an etching process of etching a TiN layer in the horizontal direction, among a series of processes for forming GAA FET (Gate-All-Around Field Effect Transistor). A part of the structure of the substrate W immediately before the start of the etching process is schematically illustrated in FIG. 3.

The substrate W to be etched includes two regions. A first region 101 is a region corresponding to a region in which p-channel metal oxide semiconductor FET (PMOS) is formed. In the first region 101, a plurality of silicon nano-sheets (Si-NS) covered with a hafnium oxide layer (HfOₓ) over the entire surface are provided at intervals in the vertical direction. The plurality of silicon nano-sheets are surrounded by, for example, TiN formed by the atomic layer deposition (ALD) method. A second region 102 is a region corresponding to a region in which n-channel metal oxide semiconductor FET (NMOS) is formed. The structure of the second region 102 immediately prior to the state illustrated in FIG. 3 is substantially the same as that of the first region 101.

Immediately prior to the state illustrated in FIG. 3, the first region 101 of the substrate W is masked against etching and the second region 102 is not masked, and a dry etching is performed in this state. For this reason, most of the TiN in the second region 102 is removed except for the portions between the silicon nano-sheets. As a result, the substrate W includes a recess 104 between the first region 101 and the second region 102. At least a portion of the TiN in the second region 102 may be exposed to a side surface (e.g., a sidewall) of the recess 104.

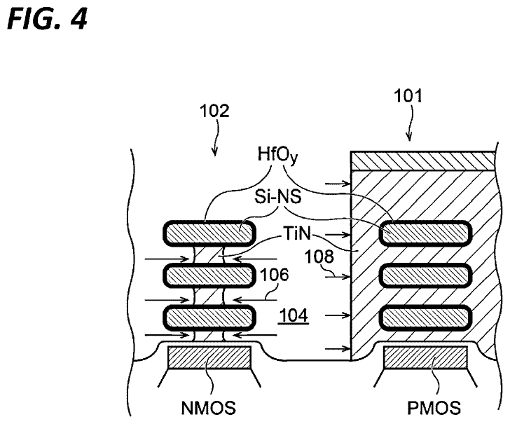

An aspect of the substrate processing method according to an embodiment of the present disclosure is performed with the intention of completely removing TiN in a narrow gap between the silicon nano-sheets in the second region in the state illustrated in FIG. 3, while ensuring that the TiN etching in the first region does not expose the silicon nano-sheets. To achieve this, it is required that the etching rate of TiN along the narrow gaps (see, e.g., the arrows 106 in FIG. 4) be as close as possible to the etching rate of a surface (see, e.g., the arrows 108 in FIG. 4) that faces a relatively wider space (compared to the narrow gap). In addition, FIG. 4 illustrates a state in which the etching of TiN described below proceeds midway.

In view of the above, a series of processes for etching TiN will be described below.

### <Processing Conditions Common to Series of Processes>

The substrate W to be processed (e.g., a silicon substrate with GAA FET formed thereon) is carried into the processing unit 16 and held by the substrate holding unit 42. Then, the substrate W is rotated. The rotation of the substrate W continues until a series of processes is completed. Unless otherwise specified, the processing liquid (e.g., DHCl, HNO₃, HCl, and DIW) is discharged from the corresponding nozzle toward the surface of the substrate W to wet the center portion of the rotating substrate W (e.g., the rotation center or a position slightly offset from the rotation center of the substrate W), thereby covering the entire surface of the substrate W with the processing liquid.

### <Pre-Processing Step>

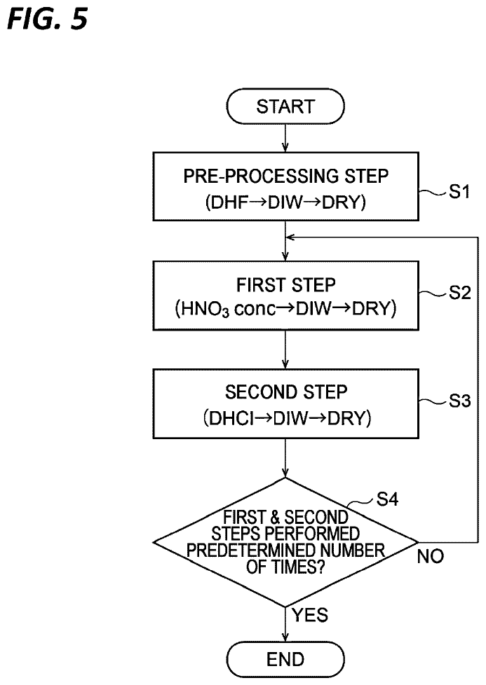

DHCl is supplied to the surface of the rotating substrate W, and the natural oxide film attached to the surface of the substrate W is removed. As a result, the surface of the substrate W is hydrophilized, thus facilitating the subsequent processing. Then, the supply of DHCL is stopped and the rinse liquid (e.g., DIW) is supplied to the surface of the substrate W to remove DHCl and byproducts from the surface of the substrate. Then, the supply of the rinse liquid is stopped while the substrate W is still rotating, and the DIW is removed from the surface of the substrate W, by, for example, the spin drying, after which the process immediately proceeds to the next step (e.g., S1, in the flowchart of FIG. 5).

In addition, when hafnium oxide (H_{f}O₂) or amorphous silicon (a-Si), which may be etched by DHCl, is exposed on the surface of the substrate W, the pre-processing step is not performed. In addition, when the hydrophilicity of the surface of the substrate W is sufficiently high, the pre-processing step may not be performed.

### <First Step (TiN Oxidation Step)>

Subsequently, HNO₃ is supplied to the surface of the rotating substrate W for a predetermined time period. As a result, the surface of TiN exposed to HNO₃ and the vicinity thereof are oxidized to form a TiO₂ film. Then, the supply of HNO₃ is stopped and the rinse liquid (e.g., DIW) is supplied to the surface of the substrate W to remove HNO₃ and byproducts from the surface of the substrate W. Then, the supply of the rinse liquid is stopped while the substrate W is still rotating, and the DIW is removed from the surface of the substrate W by, for example, a spin drying, after which the process immediately proceeds to the next step (e.g., S2, in the flowchart of FIG. 5).

### <Second Step (Oxide Etching Step)>

Subsequently, HCl (e.g., DHCl) is supplied to the surface of the rotating substrate W for a predetermined time period. As a result, the surface of TiN exposed to the HCl and the TiO₂ portion (the portion oxidized in the first step) in the vicinity thereof are dissolved (etched) by the HCl. Then, the supply of the HCl is stopped and the rinse liquid (e.g., DIW) is supplied to the surface of the substrate W to remove the HCl and byproducts from the surface of the substrate W. Then, the supply of the rinse liquid is stopped while the substrate W is still rotating, and the DIW is removed from the surface of the substrate W by, for example, a spin drying, after which the process immediately proceeds to the next step (e.g., S3, in the flowchart of FIG. 5).

The first step and the second step are each performed at least once. In this example, as illustrated in FIG. 4, a layer including a second material (e.g., a layer including TiN) sandwiched between the layers including a first material (e.g., a layer including Si-NS surrounded by HfOₓ) is etched in a horizontal direction (e.g., in a direction perpendicular to the stacking direction). When the structure is etched, it is generally difficult to achieve a desired etch amount of TiN only by performing the first step and the second step once. In this case, the first step and the second step may be alternately and repeatedly performed multiple times (e.g., several tens of times) until the desired etch amount is obtained (e.g., until the TiN layer between the layers including the first material is completely removed) (e.g., S2 to S4 in the flowchart of FIG. 5).

The reason for drying the substrate W when transitioning from the first step to the second step is that when the rinse liquid DIW remains on the substrate W, the HCl supplied to the substrate W in the second step is diluted, making it impossible to sufficiently etch the oxidized TiN layer. In particular, once etching has progressed to a certain extent, replacing the DIW in the narrow space between two adjacent layers including the first material (e.g., layers including Si-NS surrounded by HfOₓ) with hydrochloric acid requires a relatively long time. For this reason, from the viewpoint of shortening the processing time, the substrate W may be dried when the process transitions from the first step to the second step.

The reason for drying the substrate W when transitioning from the second step of the N-th cycle to the first step of the (N+1)-th cycle is that when the rinse liquid (DIW) remains on the substrate W, HNO₃ supplied to the substrate W in the first step of the (N+1)-th cycle is diluted. When HNO₃ is diluted, not only will it be impossible to oxidize TiN to the desired state, but there is also a concern that TiN will be dissolved or portions that are not to be etched will be etched. Therefore, the substrate W may be dried when transitioning from the second step of the N-th cycle to the first step of the (N+1)-th cycle, not only from the viewpoint of shortening the processing time, but also from the viewpoint of ensuring that TiN is oxidized to the desired state.

As described above, the substrate only needs to be in a dried state when transitioning from the first step to the second step (the same applies when transitioning from the pre-processing step to the first step of the first cycle), as well as when transitioning from the second step of the N-th cycle to the first step of the (N+1)-th cycle, and the substrate may be dried by any method. For example, after a rinsing step is performed by supplying a chemical liquid (e.g., HNO₃ or HCl), the rinse liquid may be replaced with an organic solvent (e.g., a liquid that is compatible with water and has a lower surface tension than water) for drying, such as IPA, after which a spin drying may be performed. The spin drying may be performed while spraying an inert gas such as nitrogen gas or a low-humidity gas onto the substrate W.

In addition, when the second step is the last second step for one substrate W, the series of processes on the substrate W may be completed with the final spin drying on the substrate W in the second step as the final step. Alternatively, after the supply of the rinse liquid to the substrate W in the second step is completed, before the substrate W is spin dried, the rinse liquid on the substrate W may be replaced with an organic solvent for drying, such as IPA, and then the spin drying on the substrate W may be performed.

When HNO₃ is being supplied to the substrate in the first step and/or when HCl is being supplied to the substrate W in the second step, the rotation speed of the substrate W may be changed, or the substrate W may be subjected to an oscillation (e.g., repetition of forward rotation and reverse rotation).

### Chemical Reaction According to Embodiment

The chemical reaction occurring in the embodiment described above will be described below.

In the first step, when HNO₃ is supplied to the TiN layer, the following reaction occurs and TiN (titan nitride) becomes TiO₂ (titan oxide).

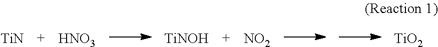

In the second step, when the HCl is supplied to the TiN layer having the surface oxidized to TiO₂, the following reaction occurs, producing TiCl₄ (titanium (IV) chloride). Titanium chloride (IV) is soluble in HCl, so Ti, which forms TiO₂, dissolves in the liquid and is removed from the TiN layer.

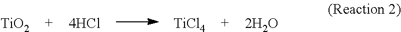

In Reaction 1, the reaction that produces TiO₂, which is readily soluble in the HCl, using TiN as a starting material, that is, the oxidation reaction is completed. For this reason, in Reaction 2, only the dissolution reaction of TiO₂ needs to occur. As described above, since different reactions such as oxidation and dissolution are performed individually in the first step and the second step, respectively, the efficiency of each step is improved, and the TiN film may be etched and removed efficiently overall. Hereinafter, another known method for removing the TiN film will be described.

### <Chemical Reaction According to First Known Method Using SC2>

The first known method is a method that sequentially performs a step of wet etching TiN by supplying SC2 to the substrate W, a DIW rinse step, and a spin drying step. Here, SC2 is, for example, a mixed solution of HCl:hydrogen peroxide water:water with mixing ratio of 1:1:50.

$$\begin{matrix}〈 Equation 1 〉 & \\ TiN \to T {i}^{4 +} : 3 {H}_{2} {O}_{2} + T i N + 2 HCl \to {Ti ( O H )}_{2} {Cl}_{2} + 3 {H}_{2} O + NO & ( 1 )\end{matrix}$$

$$T iN \to T {i}^{3 +} : 3 {H}_{2} {O}_{2} + 2 T i N + 4 HCl \to Ti ( OH ) {Cl}_{2} + {H}_{2} O + {N}_{2} \qquad ( 2 )$$

When TiN is exposed to SC2, the two reactions 1 and 2 described above proceed. Typically, the reaction of Reaction 1 is dominant. H₂O₂ oxidizes TiN to generate Ti(OH)₂⁺⁺ or Ti(OH)⁺⁺, which then forms a complex with Cl⁻. As a result, Ti dissolves in the liquid.

<Chemical Reaction According to Second Known Method Using H₂O₂ (Hydrogen Peroxide Water)>

The second known method is a method that sequentially performs a step of wet etching TiN by supplying hydrogen peroxide water to the substrate, a DIW rinse step, and a spin drying step.

$$\begin{matrix}〈 Equation 2 〉 & \\ TiN + 3 {H}_{2} O + 2 {H}_{2} {O}_{2} \to {TiO}^{+ +} \cdot {H}_{2} {O}_{2} + 3 {OH}^{-} + {NH}_{4} OH & \end{matrix}$$

$$TiN + 3 {H}_{2} O + 2 {H}_{2} {O}_{2} \to {TiO}^{+ +} \cdot {HO}_{2}^{-} + {H}^{+} + 3 {OH}^{-} + {NH}_{4} OH$$

When TiN is exposed to hydrogen peroxide water, first, TiO⁺⁺ which is a reaction intermediate is formed, which then forms a complex with H₂O₂ or HO₂⁻. As a result, Ti dissolves in the liquid.

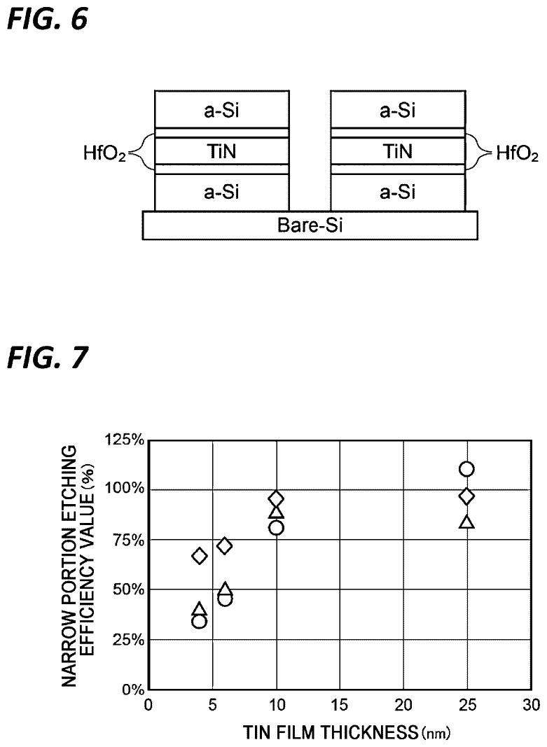

Experimental results comparing the method according to the embodiment described above with the first and second known methods described above will be described below. A sample having the stacked structure illustrated in FIG. 6 was prepared. This sample emulated the structure of GAA. FET described above. An a-Si (amorphous silicon) film, an HfO₂ film having a thickness of 2 nm, a TiN film (e.g., formed by ALD process), an HfO₂ film having a thickness of 2 nm, and an a-Si film were sequentially stacked on the bare silicon substrate, in an order from the bottom, and then a recess reaching the bare silicon substrate was formed in the center by dry etching. The thickness of the TiN film was 4 nm, 6 nm, 10 nm, and 25 nm. The end of the TiN film was exposed to the sidewall of the recess.

With the sample having this stacked structure, the TiN film was etched using the method according to the embodiment and the first and second known methods described above. For all of the method according to the embodiment and the first and second known methods described above, the pre-processing step described above was performed. In the pre-processing step, DHCl at room temperature with a concentration of 0.57 wt % was supplied to the rotating sample for 5 minutes, followed by DIW rinsing and spin drying.

With the method according to the embodiment, the chemical liquid processing in the first step (i.e., a processing using a reactive chemical liquid, excluding the rinsing process and spin drying process among the processes; the same applies hereinafter) was performed by supplying 69 wt % of HNO₃ at room temperature to the rotating sample for 2 minutes. The chemical liquid processing in the second step was performed by supplying 6.9 wt % of DHCl at 40° C. to the rotating sample for 2 minutes. The first step and the second step were alternately performed 44 times. In the first and second steps, after the chemical liquid processing was completed, the rinsing process and the spin drying process were performed.

The chemical liquid processing in the first step was performed by supplying the SC2 at 50° C. to the rotating sample for 7 minutes. The chemical liquid processing in the second step was performed by supplying the diluted hydrogen peroxide water (e.g., a mixed solution of hydrogen peroxide water:water with the mixing ratio of 1:5) at 50° C. to the rotating sample for 8 minutes.

For the sake of simplicity, the etching of the sample described above will also be referred to as “narrow portion TiN film etching.”

In addition, under the same processing conditions described above, a substrate having a flat TiN film formed on its flat surface was subjected to the etching of the TIN film (for simplicity, this will also be referred to as “flat TiN film etching”) under the same conditions as the method according to the embodiment performed on the sample described above, as well as the first and second known methods described above.

The results of the experiment are illustrated in the graph of FIG. 7. The horizontal axis represents a film thickness of the TiN film in the sample of FIG. 6. The vertical axis represents a value (%) obtained by dividing the etch amount of the narrow portion TiN film etching by the etch amount of the flat TiN film etching, and multiplying the result by 100 (hereinafter, this will also be referred to as “narrow portion etching efficiency value”). In the graph, the diamonds (⋄), triangles (Δ), and circles (∘) represent the results of the method according to the embodiment, the first known method, and the second known method, respectively. In addition, when performing an etching of the narrow portion TiN film etching, the thinner the TiN film, the deeper the liquid should be introduced into the narrow space as the etching process progresses. For this reason, the thinner the TiN film, the more difficult it becomes to proceed with etching in the horizontal direction. Therefore, across all the methods, thinner TiN films exhibit lower narrow portion etching efficiency value.

As is apparent from the graph of FIG. 7, the method according to the embodiment described above had a higher narrow portion etching efficiency value than the first and second known methods described above, even when the thickness of the TIN film was reduced.

By performing the processing with HNO₃ in the first step, a TiO₂ film is formed on the surface of the TiN layer and in the vicinity thereof. When the TiO₂ film is formed on the surface of the TiN layer and in the vicinity thereof, the reaction hardly proceeds from there. For this reason, it is unlikely that there is a large difference in thickness of the TiO₂ film formed on the surface of TiN, when the TiN layer faces a relatively wide space (e.g., the recess in the example of FIG. 6) and when it faces a relatively narrow space (e.g., a gap between two vertically adjacent a-Si films (sandwiched above and below by HfO₂ films) in the example of FIG. 6). In the second step, with the supply of the HCl, only the TiO₂ coating is dissolved, and the underlying TiN layer remains. For this reason, it is considered that a high narrow portion etching efficiency value may be obtained.

When TiN is etched by the first and second known methods described above, since the TiN layer itself is dissolved in the liquid, the film of TiO₂ is not formed. Therefore, the etching rate of the TiN layer facing a relatively wide space, where the chemical liquid in the vicinity of the etched portion is likely to be replaced by a fresh chemical liquid, is likely to be higher than the etching rate of the TiN layer facing a relatively narrow space. For this reason, it is considered that the narrow portion etching efficiency value will be lowered.

In addition, when dilute nitric acid is used instead of HNO₃ in the first step, since the TiN layer itself is dissolved in the liquid, the film of TiO₂ is not formed. Therefore, even in this case, the etching rate of the TiN layer facing a relatively wide space, where the chemical liquid in the vicinity of the etched portion is likely to be replaced by a fresh chemical liquid, is likely to be higher than the etching rate of the TiN layer facing a relatively narrow space. In addition, dilute nitric acid may attack materials other than TiN. Therefore, HNO₃ may be used in the first step.

According to the embodiment described above, when etching TiN, it is possible to perform etching efficiently while reducing the influence of the shape of the film formed from TiN or the environment around the film. According to the embodiment described above, it is possible to reduce a decrease in the etch amount of the film in the narrow space (e.g., recess or horizontal recess) in the pattern. In addition, for this reason, when there are both a TiN film facing a relatively wide space and a TiN film facing a relatively narrow space on one substrate, it is possible to prevent the occurrence of an event in which the etch amount of the TiN film facing the relatively narrow space is significantly smaller than the etch amount of the TiN film facing the relatively wide space.

In addition to the above example, as an example of a combination of a film facing a relatively wide space and a film facing a relatively narrow space, a combination of a film formed on the surface of the substrate W and a film formed on the inner surface (e.g., bottom or side surface of the recess) of the recess formed on the surface of the substrate W is also possible.

It is conceivable that oxidation of the TiN film is performed in a bake unit that heats the substrate in an oxidizing atmosphere (e.g., an air atmosphere), and subsequent etching is performed in a liquid processing unit. In this case, the total processing time is increased, especially due to the transfer of the substrate between units. However, according to the embodiment described above, since one substrate may be processed by one liquid processing unit (liquid processing module), the process time may be shortened. In addition, the equipment cost may also be reduced.

The substrate is not limited to the semiconductor wafers, and may be any type of substrate used in the technical field of semiconductor manufacturing such as a glass substrate and a ceramic substrate.

As described above, an etch target film is not limited to the TiN film provided in the narrow spaces between a plurality of silicon films sandwiched between or surrounded by the HfOₓ films. The target for etching is not limited to TiN, and may be one or more metals selected from the group consisting of TiN, SiN, W, and Mo. The term “metal” as used herein also includes a nitride such as TIN, SiN, and the like, which is a good conductor material treated as a metal in the technical field of semiconductor manufacturing. The series of steps (first step→second step) according to the embodiment described above is not limited to etching the metal film provided in the narrow space, but may be used to etching the metal film formed on the surface of the substrate facing a wide space. The films other than the etch target film in the vicinity of the etching target film are not limited to a plurality of silicon films sandwiched between or surrounded by the HfOₓ films, but may be any films including a material that is not attacked by the processing liquids used in the first and second steps, or that is attacked to a negligible extent.

The processing liquid used in the first step (e.g., an oxidizing agent) is not limited to HNO₃, but may be any liquid that can oxidize the etch target film without substantially dissolving the etching target film, and may be a liquid that does not attack the film in the vicinity of the etching target film or that only attacks the film in the vicinity to a negligible extent. Examples of such a liquid include ozone water, permanganese acid liquid, and periodic acid liquid.

According to the embodiment of the present disclosure, it is possible to efficiently remove the metal film.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. A substrate processing method comprising:
providing a substrate including a recess and having a region in which a metal is exposed on at least a portion of a side surface or a bottom surface of the recess;
oxidizing the exposed metal of the recess with a first processing liquid; and
etching, after the oxidizing, the oxidized metal with a second processing liquid.

2. The substrate processing method according to claim 1, wherein the oxidizing and the etching are performed in a same liquid processing section.

3. The substrate processing method according to claim 1, wherein the oxidizing and the etching are alternately and repeatedly performed at least twice or more.

4. The substrate processing method according to claim 3, wherein the oxidizing includes oxidizing the exposed metal with the first processing liquid, rinsing the substrate, and then, drying the substrate, and
the etching includes etching the oxidized metal with the second processing liquid, rinsing the substrate, and then, drying the substrate.

5. The substrate processing method according to claim 1, wherein the first processing liquid is concentrated nitric acid (HNO₃).

6. The substrate processing method according to claim 1, wherein the first processing liquid is ozone water.

7. The substrate processing method according to claim 1, wherein the second processing liquid is hydrochloric acid (HCl).

8. The substrate processing method according to claim 1, wherein the metal is any one of TiN, SiN, W, and Mo.

9. The substrate processing method according to claim 1, wherein the metal is TiN,
the first processing liquid is concentrated nitric acid (HNO₃), and
the second processing liquid is hydrochloric acid (HCl).

10. The substrate processing method according to claim 1, wherein a pre-processing is performed before the oxidizing is performed, and
the pre-processing includes cleaning the substrate with dilute hydrofluoric acid (DHCl), rinsing the substrate, and then, drying the substrate.

11. The substrate processing method according to claim 1, wherein the metal forms at least one film among a plurality of films forming a stacked structure,
a non-etch target film including a material that is not substantially etched by the first processing liquid used in the oxidizing and the second processing liquid used in the etching is provided on both sides of the one film in a stacking direction of the plurality of films, and
the substrate processing method further comprises etching the one film from an end portion of the film exposed to the recess in a direction orthogonal to the stacking direction of the plurality of films.

12. A substrate processing apparatus comprising:
a substrate holder configured to hold and rotate a substrate;
a processing liquid supply configured to supply a first processing liquid and a second processing liquid to the substrate held by the substrate holder;
a controller configured to control at least the substrate holder and the processing liquid supply to perform a substrate processing method including:
holding and rotating, by the substrate holder, a substrate including a recess and having a region in which a metal is exposed on at least a portion of a side surface or a bottom surface of the recess;
oxidizing the exposed metal with the first processing liquid by supplying, by the processing liquid supply, the first processing liquid to the substrate; and
after the oxidizing, etching the oxidized metal with the second processing liquid by supplying, by the processing liquid supply, the second processing liquid to the substrate.

13. The substrate processing apparatus according to claim 12, wherein the controller is configured to alternately and repeatedly perform the oxidizing and the etching at least twice or more.

14. The substrate processing apparatus according to claim 13, wherein the oxidizing includes oxidizing the exposed metal by supplying the first processing liquid to the substrate, rinsing the substrate by supplying a rinse liquid to the substrate, and then spin-drying the substrate by rotating the substrate, and
the etching includes etching the oxidized metal using the second processing liquid, rinsing the substrate by supplying a rinse liquid to the substrate, and then spin-drying the substrate by rotating the substrate.

15. The substrate processing apparatus according to claim 12, wherein the first processing liquid is concentrated nitric acid (HNO₃).

16. The substrate processing apparatus according to claim 12, wherein the first processing liquid is ozone water.

17. The substrate processing apparatus according to claim 12, wherein the second processing liquid is hydrochloric acid (HCl).

18. The substrate processing apparatus according to claim 12, wherein the metal is any one of TiN, SiN, W, and Mo.

19. The substrate processing apparatus according to claim 12, wherein the metal is TiN,
the first processing liquid is concentrated nitric acid (HNO₃), and
the second processing liquid is hydrochloric acid (HCl).
